(19) United States
(12) Patent Application Publication
(10) Pub. No.: US 2026/0011054 A1
(43) Pub. Date: Jan. 8, 2026

(54) INFORMATION PROCESSING APPARATUS, INFORMATION PROCESSING METHOD, AND STORAGE MEDIUM

(71) Applicant: Tokyo Electron Limited, Tokyo (JP)

(72) Inventor: Ryota AOI, Hokkaido (JP)

(21) Appl. No.: 19/255,415

(22) Filed: Jun. 30, 2025

(30) Foreign Application Priority Data
Jul. 4, 2024 (JP) 2024-108325

(51) Int. Cl. G06T 11/20; H01L 21/02

(52) U.S. Cl. CPC G06T 11/206; H01L 21/02

(57) ABSTRACT

Provided is an information processing apparatus including an acquisition unit that acquires sensor data including a plurality of sensor values measured by a substrate processing apparatus and attribute information that affects a temporal change in the substrate processing apparatus, a classification unit that classifies the sensor data based on the attribute information, and a display unit that displays a plot corresponding to the sensor data in a different mode for each classification, on a correlation graph between the plurality of sensor values.

### CROSS REFERENCES TO RELATED APPLICATIONS

This application is based on and claims priority from Japanese Patent Application No. 2024-108325, filed on Jul. 4, 2024, with the Japan Patent Office, the disclosure of which is incorporated herein in its entirety by reference.

### TECHNICAL FIELD

The present disclosure relates to an information processing apparatus, an information processing method, and a storage medium.

### BACKGROUND

A technique for monitoring factors that affect the state of a substrate processing apparatus is known. For example, Japanese Patent Laid-Open Publication No. 2006-228911 discloses a semiconductor manufacturing apparatus that displays correlation data between one monitoring target and another monitoring target on a two-axis coordinate system based on multiple sets of values of the one monitoring target and values of the other monitoring target.

### SUMMARY

According to one aspect of the present disclosure, there is provided an information processing apparatus including an acquisition unit that acquires sensor data including a plurality of sensor values measured by a substrate processing apparatus and attribute information that affects a temporal change in the substrate processing apparatus, a classification unit that classifies the sensor data based on the attribute information, and a display unit that displays a plot corresponding to the sensor data in a different mode for each classification, on a correlation graph between the plurality of sensor values.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a block diagram illustrating an example of an overall configuration of a substrate processing system.

FIG. 2 is a schematic cross-sectional view illustrating an example of a substrate processing apparatus.

FIG. 3 is a block diagram illustrating an example of a hardware configuration of a computer.

FIG. 4 is a block diagram illustrating an example of a functional configuration of an analysis apparatus.

FIG. 5 is a flowchart illustrating an example of an analysis method.

FIG. 6 is a diagram illustrating a first example of a display mode.

FIG. 7 is a diagram illustrating a second example of a display mode.

FIG. 8 is a diagram illustrating a third example of a display mode.

FIG. 9 is a diagram illustrating an example of an analysis screen that shows a correlation graph between heater temperature and resistance value.

FIG. 10 is a diagram illustrating an example of an analysis screen that shows a correlation graph between pressure and valve angle.

### DETAILED DESCRIPTION

In the following detailed description, reference is made to the accompanying drawings, which form a part hereof. The illustrative embodiments described in the detailed description, drawings, and claims are not meant to be restricting. Other embodiments may be utilized, and other changes may be made without departing from the spirit or scope of the subject matter presented here.

Hereinafter, embodiments for carrying out the present disclosure will be described with reference to the drawings. In each drawing, the same reference numerals may be given to the same components, and redundant descriptions may be omitted.

### Embodiment

One embodiment of the present disclosure relates to a substrate processing system including a substrate processing apparatus for processing a substrate, which is an example of a processing target. In the present embodiment, the substrate processing apparatus thermally processes a semiconductor wafer, which is an example of a substrate, inside a processing container. Further, the substrate processing system includes an analysis apparatus that analyzes sensor data indicating sensor values measured by sensors provided in the substrate processing apparatus.

The substrate processing apparatus is provided with one or more sensors for measuring the state of the substrate processing apparatus. When the substrate processing apparatus executes a process for processing a substrate, the sensors provided in the substrate processing apparatus measure predetermined sensor values at predetermined time intervals. Time-series data of the sensor values measured by each sensor is stored in a storage device included in the substrate processing apparatus, or in a storage device connected to the substrate processing apparatus via a network.

To analyze the state of the substrate processing apparatus, it is known to display a correlation graph between a plurality of sensor values. As an example, a known technique involves extracting time-series data of sensor values measured during a period, for which a process recipe is executed, under a predetermined condition, and displaying a correlation graph between the extracted sensor values and other sensor values.

The correlation graph is a graph that indicates the correlation between a plurality of sensor values by plotting data including the plurality of sensor values in a low-dimensional space where each axis corresponds to one of the plurality of sensor values. The correlation graph between a plurality of sensor values does not have a time-related axis, and therefore, may not visualize the time series of each datum. Therefore, it is difficult to analyze a temporal change in the correlation between a plurality of sensor values with conventional correlation graphs.

To analyze a temporal change in the correlation between a plurality of sensor values, for example, it is conceivable to compare and analyze the correlation graph between a plurality of sensor values with a time-series graph in which each sensor value is displayed in a time-series manner. The time-series graph is a graph that shows a temporal change in sensor values by plotting the sensor values in a low-dimensional space with the sensor values and time as axes. However, manually comparing a large number of graphs with different axes requires a significant effort. As such, in the conventional techniques, a great deal of labor is required to analyze a temporal change in the correlation between a plurality of sensor values.

The present embodiment aims to visualize a temporal change in the substrate processing apparatus. Therefore, in the present embodiment, sensor data including a plurality of sensor values is classified based on attribute information that affects a temporal change in the substrate processing apparatus, and plots corresponding to the sensor data are displayed in a different mode for each classification on a correlation graph between the plurality of sensor values.

In one aspect, according to the present embodiment, it is possible to visualize a temporal change in the substrate processing apparatus since a correlation graph in which plots are displayed in a mode corresponding to an attribute that affects a temporal change in the substrate processing apparatus is displayed. In another aspect, according to the present embodiment, it is possible to easily analyze a temporal change in the substrate processing apparatus since a temporal change in the correlation between a plurality of sensor values may be visually recognized using only a correlation graph.

### <System Configuration>

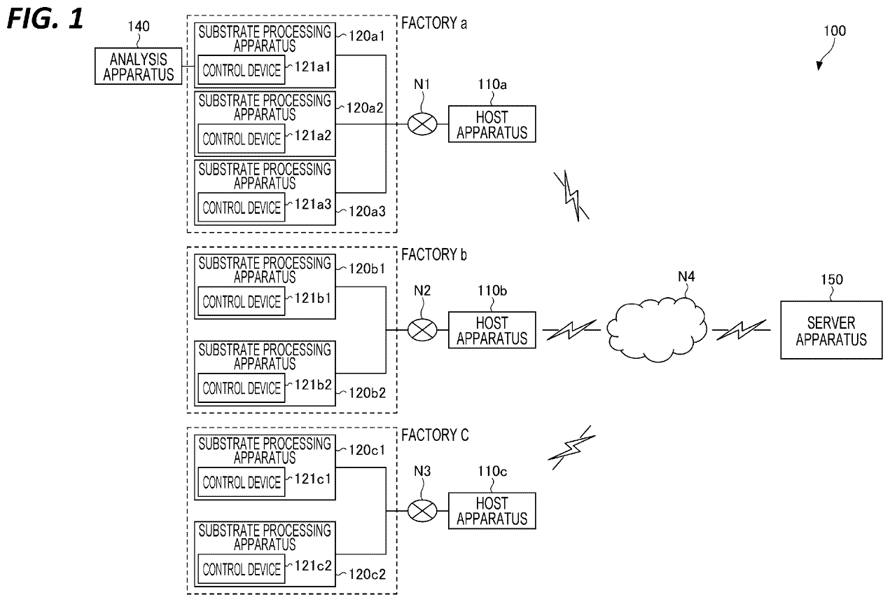

An overall configuration of a substrate processing system according to the present embodiment will be described with reference to FIG. 1. FIG. 1 is a block diagram illustrating an example of an overall configuration of a substrate processing system.

As illustrated in FIG. 1, the substrate processing system 100 includes substrate processing apparatuses 120a1 to 120a3 and control devices 121a1 to 121a3 in a factory a. The substrate processing apparatuses 120a1 to 120a3 and the control devices 121al to 121a3 are connected in a wired or wireless manner.

Further, the substrate processing system 100 includes substrate processing apparatuses 120b1 and 120b2 and control devices 121b1 and 121b2 in a factory b. The substrate processing apparatuses 120b1 and 120b2 and the control devices 121b1 and 121b2 are connected in a wired or wireless manner.

Further, the substrate processing system 100 includes substrate processing apparatuses 120c1 and 120c2 and control devices 121c1 and 121c2 in a factory c. The substrate processing apparatuses 120c1 and 120c2 and the control devices 121cl and 121c2 are connected in a wired or wireless manner.

The substrate processing apparatuses 120al to 120a3, substrate processing apparatuses 120b1 and 120b2, and substrate processing apparatuses 120c1 and 120c2 are connected to host apparatuses 110a, 110b and 110c via networks N1 to N3, respectively. Each substrate processing apparatus executes a substrate processing under the control of each control device based on instructions from the host apparatuses 110a, 110b and 110c. The host apparatuses 110a, 110b and 110c are connected to a server apparatus 150 via a network N4 such as the Internet.

In the following description, the substrate processing apparatuses 120al to 120a3, 120b1, 120b2, 120c1 and 120c2 are collectively referred to as the substrate processing apparatus 120. Further, the control devices 121a1 to 121a3, 121b1, 121b2, 121c1 and 121c2 are collectively referred to as the control device 121. The host apparatuses 110a, 110b and 110c are collectively referred to as the host apparatus 110.

The substrate processing apparatuses 120a1 to 120a3, substrate processing apparatuses 120b1 and 120b2, and substrate processing apparatuses 120c1 and 120c2 are assumed to accumulate a wide variety of data where they manage individually inside respective apparatuses thereof.

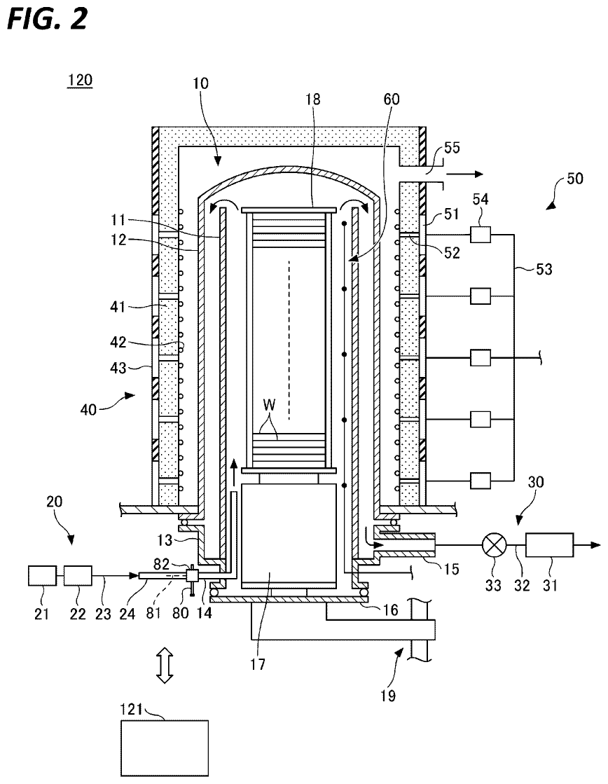

An analysis apparatus 140 is connected to the substrate processing apparatus 120 including the substrate processing apparatus 120a1, thereby continuously acquiring the accumulated data stored in each substrate processing apparatus 120. The example of FIG. 2 illustrates the connection of the analysis apparatus 140 to the substrate processing apparatus 120al but is not limited thereto. Hereinafter, in the present embodiment, details of a case where the analysis apparatus 140 is connected to the substrate processing apparatus 120al will be described.

It goes without saying that the substrate processing system 100 illustrated in FIG. 1 is merely an example, and there are various other system configuration examples depending on the use or purpose. The categorization of apparatuses such as the host apparatus 110, substrate processing apparatus 120, control device 121, analysis apparatus 140, and server apparatus 150 illustrated in FIG. 1 is merely an example. For example, the numbers of factories, host apparatuses 110, substrate processing apparatuses 120, control devices 121, analysis apparatuses 140, and others are merely an example and are not limited thereto.

For example, the substrate processing system 100 may have various configurations such as a configuration in which at least two of the substrate processing apparatus 120, control device 121, host apparatus 110, analysis apparatus 140, and server apparatus 150 are integrated, or a configuration in which they are further divided. For example, the control device 121 may be configured to collectively control a plurality of substrate processing apparatuses 120, may be provided in a one-to-one ratio for each substrate processing apparatus 120, or may be integrated with the substrate processing apparatus 120.

The analysis apparatus 140 may be implemented by the host apparatus 110, or may be implemented by the server apparatus 150. In this case, the analysis apparatus 140 becomes unnecessary. Further, the analysis apparatus 140 may be implemented by the control device 121. The analysis apparatus 140 may be implemented by a control device that collectively controls a plurality of control devices 121.

### <Substrate Processing Apparatus>

An example of a substrate processing apparatus according to the present embodiment will be described with reference to FIG. 2. FIG. 2 is a schematic cross-sectional view illustrating a vertical thermal processing apparatus, which is an example of a substrate processing apparatus.

The vertical thermal processing apparatus 120 according to the present embodiment is a substrate processing apparatus that simultaneously accommodates a large number of semiconductor wafers W, which are an example of a processing target, to perform a thermal processing such as oxidation, diffusion, and reduced-pressure chemical vapor deposition (CVD). As illustrated in FIG. 2, the vertical thermal processing apparatus 120 includes a processing container 10, a gas supply unit 20, an exhaust unit 30, a heating unit 40, a cooling unit 50, and the control device 121, among others.

The processing container 10 has a substantially cylindrical shape. The processing container 10 includes an inner tube 11, an outer tube 12, a manifold 13, an injector 14, a gas outlet 15, a lid 16, and others. The inner tube 11 has a substantially cylindrical shape. The outer tube 12 has a ceilinged substantially cylindrical shape, and both the inner tube 11 and the outer tube 12 form a dual tube structure. The inner tube 11 and the outer tube 12 are made of, for example, a heat-resistant material such as quartz.

The manifold 13 has a substantially cylindrical shape. The manifold 13 supports the lower ends of both the inner tube 11 and the outer tube 12. The manifold 13 is made of, for example, stainless steel. The injector 14 passes through the manifold 13 to extend horizontally inside the inner tube 11, and is then bent into an L-shape to extend upward inside the inner tube 11. The injector 14 has a base connected to a gas introduction pipe 24 and an open tip. The injector 14 discharges a processing gas (hereinafter simply referred to as “gas”) introduced through the gas introduction pipe 24 into the inner tube 11 from an opening at the tip thereof. There may be a plurality of injectors 14.

The gas outlet 15 is formed in the manifold 13. The processing gas is exhausted through the gas outlet 15 by the exhaust unit 30. The lid 16 airtightly seals an opening at the lower end of the manifold 13. The lid 16 is made of, for example, stainless steel. A wafer boat (substrate holder) 18 is disposed on the lid 16 via a heat reservoir 17. The heat reservoir 17 and wafer boat 18 are made of, for example, a heat-resistant material such as quartz.

The wafer boat 18 holds a plurality of semiconductor wafers W approximately horizontally at predetermined intervals in the vertical direction. The wafer boat 18 is loaded into the processing container 10 when a lifting mechanism 19 raises the lid 16, and is accommodated inside the processing container 10. The wafer boat 18 is unloaded from the processing container 10 when the lifting mechanism 19 lowers the lid 16.

The gas supply 20 includes a gas source 21, an integrated gas system (IGS) 22, an external pipe 23, and the gas introduction pipe 24. The gas source 21 is a source of the processing gas and includes, for example, a film forming gas source, a cleaning gas source, and a purge gas source. The IGS 22 is an integrated circuit of gas pipes, where pipe groups connected respectively to, e.g., the film forming gas source, cleaning gas source, and purge gas source of the gas source 21 are integrated. A flow rate controller is provided inside the IGS 22 to control the flow rate of a gas flowing through each pipe. The flow rate controller includes, for example, a mass flow controller and an on-off valve.

The IGS 22 is connected to the external pipe 23. The external pipe 23 is connected to the gas introduction pipe 24. A heater (not illustrated) is wound around the outer periphery of the external pipe 23 to heat the external pipe 23. The gas introduction pipe 24 is connected to the processing container 10 to introduce the gas to the inside of the processing container 10. In other words, the processing gas from the gas source 21 is controlled for the flow rate thereof by the flow rate controller inside the IGS 22, and is heated while flowing through the external pipe 23 and is then directed into the gas introduction pipe 24, thereby being finally supplied from the gas introduction pipe 24 into the processing container 10 through the injector 14. The injector 14 functions as a gas inlet of the processing container 10.

A gas pipe joint 82 connected to the gas introduction pipe 24 is provided near the gas inlet of the processing container 10. A temperature sensor 80 is configured to pass through the joint 82. The temperature sensor 80 is configured to measure the temperature of the gas inside the gas introduction pipe 24. The temperature sensor 80 transmits the measured temperature to the control device 121. Further, a second heater 81 is arranged inside the gas introduction pipe 24. The second heater 81 is configured to heat the gas inside the gas introduction pipe 24.

The exhaust unit 30 includes an exhaust device 31, an exhaust pipe 32, and a pressure controller 33. The exhaust device 31 is, for example, a vacuum pump such as a dry pump or turbo molecular pump. The pressure controller 33 is interposed in the exhaust pipe 32, and controls the pressure inside the processing container 10 by adjusting the conductance of the exhaust pipe 32. The pressure controller 33 is, for example, an automatic pressure control valve.

The heating unit 40 includes a heat insulator 41, a first heater 42, and an outer shell 43. The heat insulator 41 has a substantially cylindrical shape and is provided around the outer tube 12. The heat insulator 41 is made of silica and alumina as main components. The first heater 42 has a linear shape and is provided in a spiral or meandering shape on the inner periphery of the heat insulator 41. The first heater 42 is configured to enable temperature control in a plurality of zones divided in the height direction of the processing container 10. The outer shell 43 is provided to cover the outer periphery of the heat insulator 41. The outer shell 43 maintains the shape of the heat insulator 41 and reinforce the heat insulator 41. The outer shell 43 is made of a metal such as stainless steel. Further, to prevent the influence of heat on the exterior of the heating unit 40, a water cooling jacket may be provided on the outer periphery of the outer shell 43. The heating unit 40 heats the inside of the processing container 10 by generating heat through the first heater 42.

The cooling unit 50 supplies a cooling fluid toward the processing container 10 to cool the semiconductor wafer W inside the processing container 10. The cooling fluid may be, for example, air. The cooling unit 50 supplies the cooling fluid toward the processing container 10, for example, when rapidly cooling the semiconductor wafer W after a thermal processing. The cooling unit 50 includes a fluid flow path 51, an ejection hole 52, a distribution flow path 53, a flow rate adjuster 54, and a heat discharge port 55.

A plurality of fluid flow paths 51 are formed in the height direction between the heat insulator 41 and the outer shell 43. The fluid flow paths 51 are, for example, flow paths formed in the circumferential direction outside the heat insulator 41. The ejection hole 52 is formed to pass through the heat insulator 41 from each fluid flow path 51, and ejects the cooling fluid into the space between the outer tube 12 and the heat insulator 41. The distribution flow path 53 is provided outside the outer shell 43, and distributes and supplies the cooling fluid to each fluid flow path 51. The flow rate adjuster 54 is interposed in the distribution flow path 53, and adjusts the flow rate of the cooling fluid supplied to the fluid flow path 51.

The heat discharge port 55 is provided above a plurality of ejection holes 52, and discharges the cooling fluid supplied to the space between the outer tube 12 and the heat insulator 41 to the outside of the processing container 10. The cooling fluid discharged to the outside of the processing container 10 is cooled by, for example, a heat exchanger and is then supplied again to the distribution flow path 53. However, the cooling fluid discharged to the outside of the processing container 10 may be discharged without being reused.

A temperature sensor 60 detects the temperature inside the processing container

10. The temperature sensor 60 is provided, for example, inside the inner tube 11. However, the temperature sensor 60 may be provided at any position where it may detect the temperature inside the processing container 10. For example, the temperature sensor 60 may be provided in the space between the inner tube 11 and the outer tube 12. The temperature sensor 60 includes, for example, a plurality of temperature measuring components provided at different positions in the height direction corresponding to the plurality of zones. The plurality of temperature measuring components may be, for example, thermocouples or temperature measuring resistors. The temperature sensor 60 transmits the temperatures detected by the plurality of temperature measuring components to the control device 121.

The control device 121 controls an operation of the vertical thermal processing apparatus 120, thereby controlling a semiconductor process executed by the vertical thermal processing apparatus 120. The control device 121 may be, for example, a computer.

### <Computer>

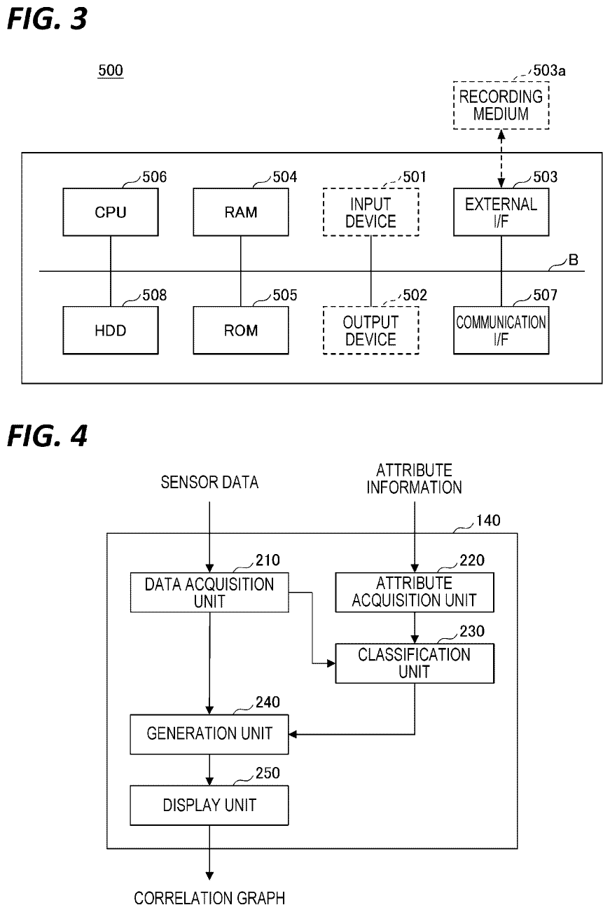

The host apparatus 110, control device 121, analysis apparatus 140, and server apparatus 150 included in the substrate processing system 100 illustrated in FIG. 1 are implemented by, for example, a computer having a hardware configuration as illustrated in FIG. 3. FIG. 3 is a block diagram illustrating an example of a hardware configuration of a computer.

As illustrated in FIG. 3, the computing unit 500 includes an input device 501, an output device 502, an external interface (I/F) 503, a random access memory (RAM) 504, a read only memory (ROM) 505, a central processing unit (CPU) 506, a communication I/F 507, and a hard disk drive (HDD) 508, among others, each of which is interconnected via a bus B. The input device 501 and the output device 502 may be connected and used as needed.

The input device 501 is, for example, a keyboard, a mouse, or a touch panel, and is used by, e.g., an operator to input each operation signal. The output device 502 is, for example, a display that displays the processing result generated by the computer 500. The communication I/F 507 is an interface that connects the computer 500 to a network. The HDD 508 is an example of a non-volatile storage device that stores programs and data.

The external I/F 503 is an interface to an external device. The computer 500 may read from and/or write to a recording medium 503a such as a secure digital (SD) memory card via the external I/F 503. The ROM 505 is an example of a non-volatile semiconductor memory (storage device) in which programs and data are stored. The RAM 504 is an example of a volatile semiconductor memory (storage device) for temporarily holding programs and data.

The CPU 506 is an arithmetic unit that reads programs and data from storage devices such as the ROM 505 and the HDD 508 onto the RAM 504 to execute a processing, thereby implementing the overall control and functions of the computer 500.

### <Function Configuration>

A functional configuration of the analysis apparatus 140 will be described with reference to FIG. 4. FIG. 4 is a block diagram illustrating an example of a functional configuration of the analysis apparatus.

As illustrated in FIG. 4, the analysis apparatus 140 includes a data acquisition unit 210, an attribute acquisition unit 220, a classification unit 230, a generation unit 240, and a display unit 250. The analysis apparatus 140 functions as the data acquisition unit 210, attribute acquisition unit 220, classification unit 230, generation unit 240, and display unit 250 when a pre-installed analysis program is executed.

For example, the data acquisition unit 210, attribute acquisition unit 220, classification unit 230, generation unit 240, and display unit 250 are implemented by the CPU 506 illustrated in FIG. 3 executing an analysis program loaded onto the RAM 504.

The data acquisition unit 210 acquires sensor data generated by the substrate processing apparatus 120. The sensor data is time-series data indicating sensor values measured by sensors provided in the substrate processing apparatus 120. In the present embodiment, the sensor data includes two or more sets of time-series data measured respectively by two or more sensors provided in the substrate processing apparatus 120.

In the present embodiment, the sensor data may include the temperature of a heater and the resistance value of the heater. The heater may be, for example, the first heater 42 that heats the processing container 10. The heater may also be, for example, the second heater 81 that heats the gas inside the gas introduction pipe 24. The heater may be, for example, a heater (not illustrated) that heats the external pipe 23.

In the present embodiment, the sensor data may include the pressure inside the processing container 10 and the opening degree of a valve that controls the pressure. The valve may be, for example, a pressure control valve, which is an example of the pressure controller 33. The opening degree of the valve may be, for example, the rotational angle of the valve.

The sensor data may include time-series data of sensor values measured when the substrate processing apparatus 120 executes a process for processing a processing target. The process may include at least one or more steps. The sensor data may include a single set of time-series data recorded through a plurality of processes for each sensor provided in the substrate processing apparatus 120, or may include multiple sets of time-series data recorded for each process or step.

The attribute acquisition unit 220 acquires attribute information that affects a temporal change in the substrate processing apparatus 120. The attribute acquisition unit 220 may acquire the attribute information based on the sensor data acquired by the data acquisition unit 210. The attribute acquisition unit 220 may also acquire the attribute information from the substrate processing apparatus 120 or the control device 121.

The attribute information may include the execution time of a process. The execution time of a process is information indicating the time at which the process was executed. The execution time of a process may be any time that allows the process to be identified. The execution time of a process may be, for example, the time at which the execution of a process started, or the time at which the execution of a process ended. The attribute acquisition unit 220 may determine the execution time of a process based on the measurement time of sensor values recorded in the sensor data.

The attribute information may be the number of executions of a process. The number of executions of a process may refer to the total number of processes executed by the substrate processing apparatus 120. As an example, the number of executions of a process may be a cumulative count of executions since the start of the operation of the substrate processing apparatus 120. The cumulative count of executions may be reset upon the execution of a predetermined processing such as cleaning. The attribute acquisition unit 220 may acquire the number of executions at the execution time of a process from log data recorded by the substrate processing apparatus 120. The attribute acquisition unit 220 may also calculate the number of executions of a process based on the sensor data accumulated in the substrate processing apparatus 120.

The attribute information may include a cumulative film thickness. The cumulative film thickness refers to the thickness of deposits adhering inside the processing container 10 as a result of a film forming process. The cumulative film thickness may be the cumulative film thickness at the execution time of a process. The attribute acquisition unit 220 may acquire the cumulative film thickness at the execution time of a process from log data recorded by the substrate processing apparatus 120. The attribute acquisition unit 220 may also estimate the cumulative film thickness based on the sensor data accumulated in the substrate processing apparatus 120.

The classification unit 230 classifies the sensor data acquired by the data acquisition unit 210. The classifier 230 may classify sensor data based on the attribute information acquired by the attribute acquisition unit 220. The classifier 230 may divide the sensor data by predetermined processing units, and classify each of divided sets of the sensor data. As an example, the classification unit 230 may divide the sensor data by process or step units, and classify the sensor data for each process or step.

The classification unit 230 may classify the sensor data into a plurality of sections depending on the attribute information. The plurality of sections may be sections into which possible values of the attribute information are divided at predetermined intervals. The interval for dividing the possible values of the attribute information may be specified by a user of the analysis apparatus 140.

For example, when the attribute information includes the execution time of a process, the classification unit 230 may divide a possible period of the execution time of a process into time sections of a predetermined length, and classify the sensor data into each time section. As an example, the classification unit 230 may classify the sensor data into time sections such as years, months, weeks, or days based on the execution time of a process.

For example, when the attribute information includes the number of executions of a process, the classification unit 230 may divide the number of possible executions into a plurality of sections at a predetermined unit width, and classify the sensor data into each section. When the attribute information includes a cumulative film thickness, the classification unit 230 may divide a possible cumulative film thickness into a plurality of sections at a predetermined unit width, and classify the sensor data into each section.

The generation unit 240 generates a correlation graph between a plurality of sensor values. The generation unit 240 may generate a correlation graph by selecting two sensor values from the sensor data acquired by the data acquisition unit 210 and plotting the sensor data on a plane (i.e., a two-dimensional space) with the selected two sensor values as axes. The generation unit 240 may generate a correlation graph by selecting three sensor values from the sensor data acquired by the data acquisition unit 210 and plotting the sensor data in a three-dimensional space with the selected three sensor values as axes.

When plotting the sensor data, the generation unit 240 may calculate a representative value for each sensor value in a predetermined processing unit. The predetermined processing unit may be, for example, a process or a step. The representative value may be, for example, any of the maximum value, minimum value, average value, or standard deviation. The average value may be, for example, the arithmetic mean. The standard deviation may be, for example, 36.

The generation unit 240 may assign information indicating the classification result from the classification unit 230 to each sensor data plotted on the correlation graph. The information indicating the classification result may also include information indicating the classified section. For example, when the attribute information includes the execution time of a process, the information indicating the classification result may be a numeric value or character string indicating a specific year.

The display unit 250 displays the correlation graph generated by the generation unit 240. The display unit 250 may display, in the correlation graph, a plot corresponding to each sensor data in a mode depending on the classification result from the classification unit 230. For example, the display unit 250 may display each plot in different shapes for each classification. The display unit 250 may display each plot in different colors for each classification. The display unit 250 may display each plot in different combinations of shapes and colors for each classification.

When displaying in different colors for each classification, it is sufficient that at least one of hue, brightness, or saturation differs for each classification. As an example, the display unit 250 may display each plot in colors with different hues and the same brightness and saturation. As an example, the display unit 250 may display each plot in colors with different brightness and the same hue and saturation (in other words, in grayscale) for each classification. Further, the color for each classification may include a fill pattern. As an example, the display unit 250 may display each plot filled with different patterns for each classification.

The display unit 250 may randomly determine a display mode for each classification. The display unit 250 may determine a display mode for each classification according to a predetermined rule. As an example, when sensor data is classified into time sections based on the execution time of a process, the display unit 250 may determine a color for each classification such that plots included in newer time sections are displayed in more visually distinguishable colors.

The display unit 250 may display an analysis screen showing the correlation graph on a display, which is an example of the output device 502. The display unit 250 may also transmit screen data including the correlation graph to another information processing apparatus such as the control device 121, a host apparatus, or a server apparatus, thus causing the analysis screen to be displayed on a display of the other information processing apparatus.

It goes without saying that the functional configuration of the analysis apparatus 140 illustrated in FIG. 4 is merely an example, and various functional configuration examples may be employed depending on the use or purpose. The division of processing units such as the data acquisition unit 210, attribute acquisition unit 220, classification unit 230, generation unit 240, and display unit 250 illustrated in FIG. 4 is also merely an example. For example, at least two of the data acquisition unit 210, attribute acquisition unit 220, classification unit 230, generation unit 240, and display unit 250 may be integrated into a single processing unit. Further, for example, at least one of the data acquisition unit 210, attribute acquisition unit 220, classification unit 230, generation unit 240, and display unit 250 may be divided into a plurality of processing units. For example, the data acquisition unit 210 and the attribute acquisition unit 220 may be configured as a single acquisition unit having both functions.

### <Processing Procedure>

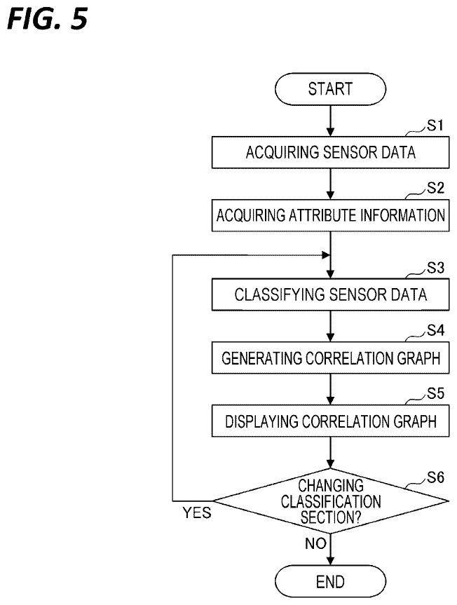

An analysis method executed by the substrate processing system 100 will be described with reference to FIG. 5. FIG. 5 is a flowchart illustrating an example of an analysis method.

In step S1, the data acquisition unit 210 of the analysis apparatus 140 acquires sensor data generated by the substrate processing apparatus 120. The sensor data includes multiple sets of time-series data indicating a plurality of sensor values measured by a plurality of sensors provided in the substrate processing apparatus 120. The data acquisition unit 210 sends the acquired sensor data to the classification unit 230 and the generation unit 240.

In step S2, the attribute acquisition unit 220 of the analysis apparatus 140 acquires attribute information that affects a temporal change in the substrate processing apparatus 120. The attribute acquisition unit 220 sends the acquired attribute information to the classification unit 230.

In step S3, the classification unit 230 of the analysis apparatus 140 receives the sensor data from the data acquisition unit 210. The classification unit 230 receives the attribute information from the attribute acquisition unit 220. The classification unit 230 classifies the sensor data based on the attribute information. The classification unit 230 sends the classification result of the sensor data to the generation unit 240.

In step S4, the generation unit 240 of the analysis apparatus 140 receives the sensor data from the data acquisition unit 210. The generation unit 240 receives the classification result of the sensor data from the classification unit 230.

The generation unit 240 generates a correlation graph between the plurality of sensor values indicated in the sensor data. The generation unit 240 calculates, for each of the plurality of sensor values, a representative value (e.g., an average value) of the sensor values for each predetermined processing unit. The generation unit 240 plots the sensor data in a low-dimensional space (e.g., a two-dimensional scatter plot) with each of the plurality of sensor values as an axis. The generation unit 240 assigns the classification result from the classification unit 230 to each plot. The generation unit 240 sends the generated correlation graph to the display unit 250.

In step S5, the display unit 250 of the analysis apparatus 140 receives the correlation graph from the generation unit 240. The display unit 250 displays, on a display, an analysis screen that displays the correlation graph. The analysis screen may include a screen component that allows for an operation for changing the sections used for classifying the sensor data.

When displaying the correlation graph, the display unit 250 displays each plot in a mode depending on the classification result assigned to each plot. The display unit 250 may display each plot in different colors for each classification. The display unit 250 may display each plot in different shapes for each classification. The display unit 250 may display each plot in different combinations of shapes and colors for each classification.

In step S5, the display unit 250 of the analysis apparatus 140 determines whether to change the sections used for classifying the sensor data. Specifically, the display unit 250 determines whether an operation for changing the sections for classifying the sensor data has been performed on the analysis screen. When the display unit 250 determines that the sections for classifying the sensor data are to be changed (YES), the processing returns to step S3. In the meantime, when the display unit 250 determines that the sections for classifying the sensor data are not to be changed (NO), the processing of the analysis method ends.

When the processing is returned to step S3, the classification unit 230 reclassifies the sensor data acquired in step S1 into the changed sections. Thereafter, the analysis apparatus 140 re-executes steps S4 and S5 based on the newly obtained classification result. Thus, the analysis screen repeatedly displays the correlation graph classified by the different sections whenever the sections for classifying the sensor data are changed.

### <Display Mode>

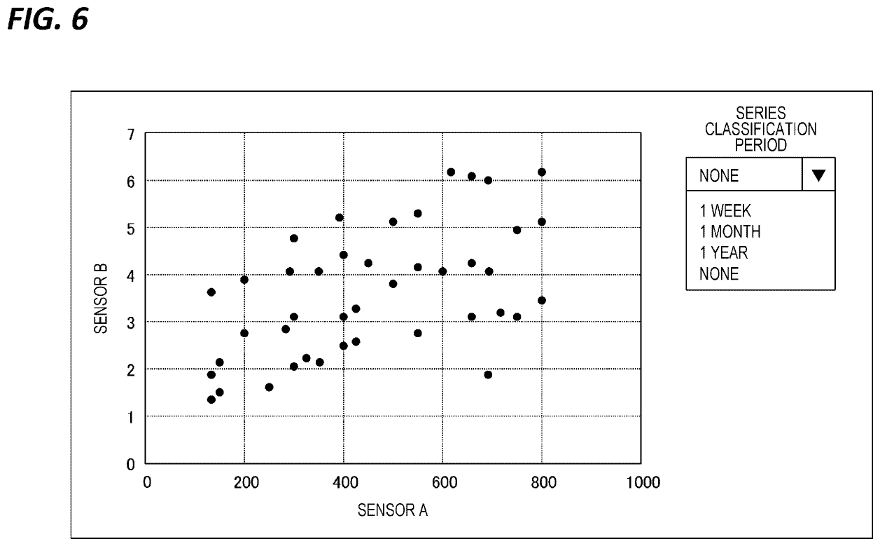

A display mode of the correlation graph will be described with reference to FIGS. 6 to 8.

FIG. 6 is a diagram illustrating a first example of a display mode. The first example of the display mode is an example of a display mode of a conventional correlation graph. That is, the first example of the display mode is an example of a correlation graph in which all plots are displayed in the same mode.

FIG. 6 is an example of a correlation graph illustrating the correlation between a first sensor value (Sensor A) and a second sensor value (Sensor B). As illustrated in FIG. 6, the correlation graph is a scatter plot in which sensor data including the values of Sensor A and Sensor B is plotted on a plane having the horizontal axis representing the first sensor value (Sensor A) and the vertical axis representing the second sensor value (sensor B). Since the correlation graph illustrated in FIG. 6 does not have a time-related axis and all plots are displayed in the same mode (black circles in FIG. 6), the temporal relationship of the sensor data corresponding to each plot is not visually recognizable.

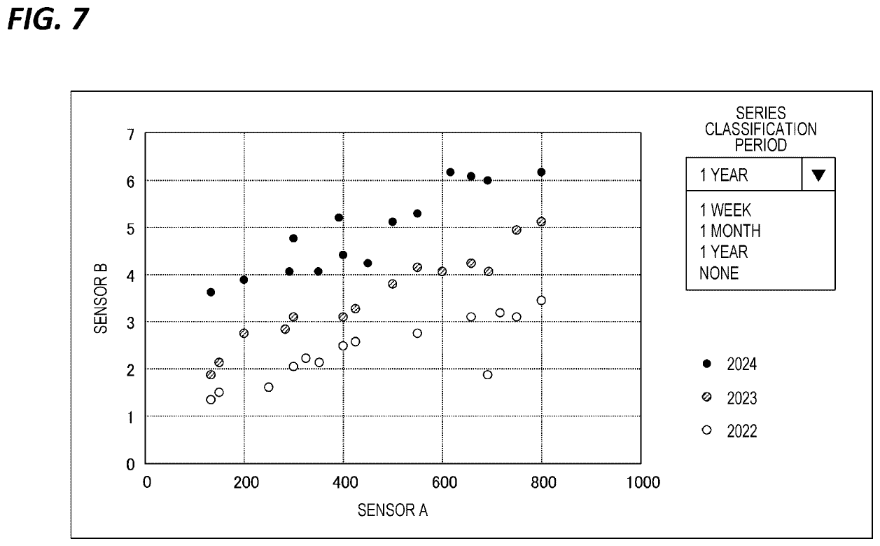

FIG. 7 is a diagram illustrating a second example of a display mode. The second example of the display mode is an example of a display mode according to the present embodiment. Specifically, the second example of the display mode is an example of a correlation graph in which plots are displayed in different colors for each classification.

FIG. 7 illustrates a case where sensor data is classified by year based on the execution time of a process and plots are displayed in different colors for each year. Specifically, the data for 2022 is filled in white, the data for 2023 is filled with hatching, and the data for 2024 is filled in black. The shape of each plot is the same (circle in FIG. 7). In FIG. 7, differences in color are represented using fill types, and are not limited to black, white, or hatching. As illustrated in FIG. 7, it is visually recognizable that the values of Sensor A are distributed within the same range regardless of the year, but the values of Sensor B are distributed within a higher value range as the year progresses.

Although FIG. 7 illustrates an example in which the plots are classified by year, the classification unit may be specified by the user. In FIG. 7, a selection field is illustrated that includes options such as one week, one month, one year, and none as selectable periods. In FIG. 7, “one year” is selected, and thus, the plots are classified by year and displayed in different modes for each classification. When “none” is selected, all plots are displayed in the same mode as in FIG. 6.

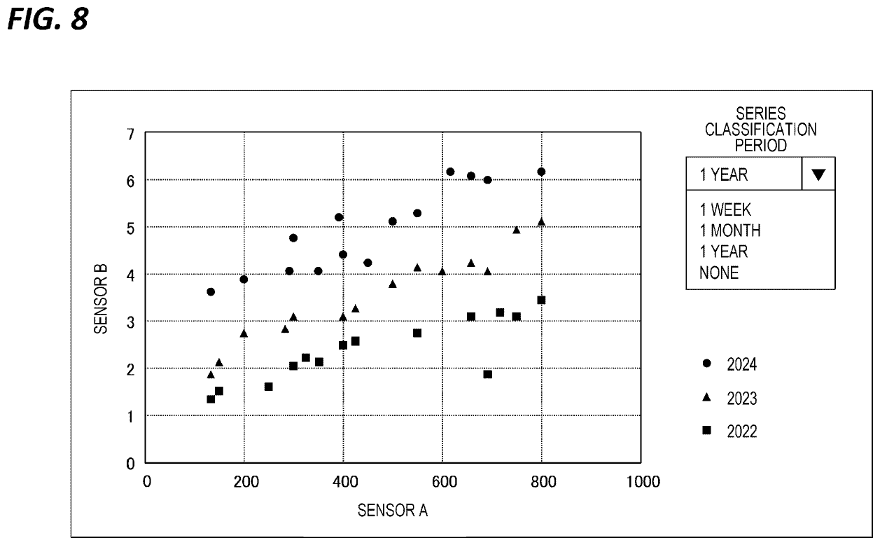

FIG. 8 is a diagram illustrating a third example of a display mode. The third example of the display mode is an example of a display mode according to the present embodiment. Specifically, the third example of the display mode is an example of a correlation graph in which plots are displayed in different shapes for each classification.

FIG. 8, similarly to FIG. 7, illustrates a case where sensor data is classified by year and plots are displayed in different shapes for each year. Specifically, the data for 2022 is indicated by squares, the data for 2023 is indicated by triangles, and the data for 2024 is indicated by circles. The color of each plot is the same (black in FIG. 8). As in FIG. 7, it is visually recognizable from FIG. 8 that the values of Sensor A are distributed within the same range regardless of the year, but the values of Sensor B are distributed within a higher value range as the year progresses.

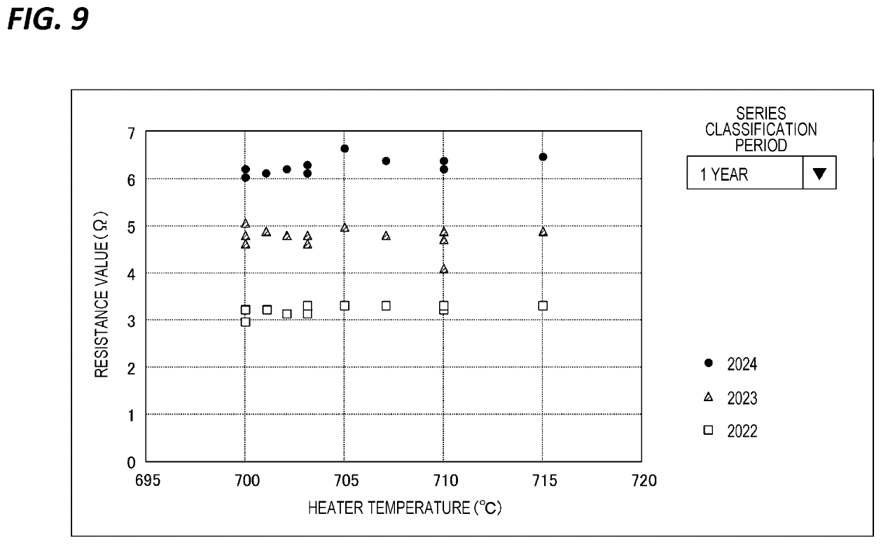

By comparing FIG. 8 or FIG. 9 with FIG. 7, it can be seen that a temporal change in the correlation between a plurality of sensor values may be easily visually recognized by classifying sensor data based on the execution time of a process and displaying plots in different modes for each classification. Therefore, according to the present embodiment, it is possible to visualize a change over the years in the substrate processing apparatus 120, facilitating the analysis of a change over the years in the substrate processing apparatus 120.

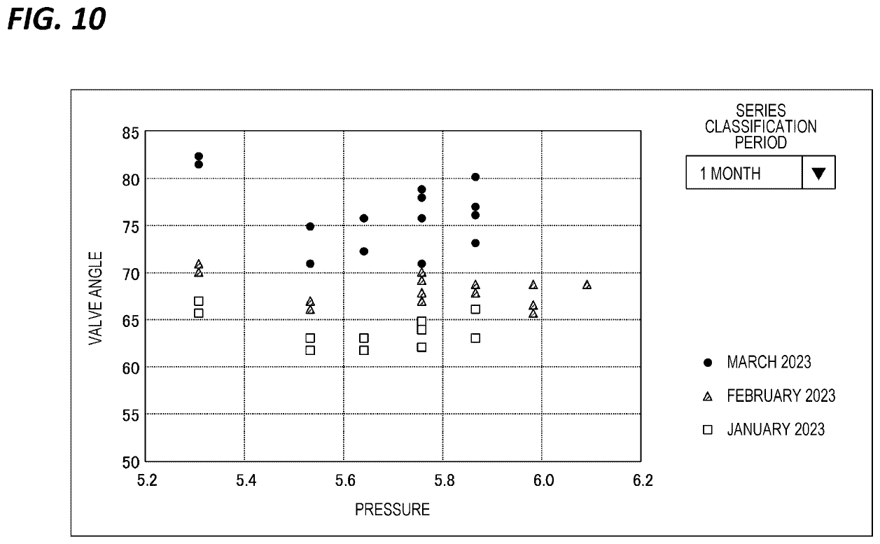

Specific display modes of a correlation graph will be described with reference to FIGS. 9 and 10.

FIG. 9 is a diagram illustrating an example of an analysis screen that shows a correlation graph between heater temperature and resistance value. In FIG. 9, the correlation between heater temperature and resistance value is plotted using different combinations of colors and shapes for each year. Specifically, the data for 2022 is indicated by white squares, the data for 2023 is indicated by triangles filled with hatching, and the data for 2024 is indicated by black circles. As illustrated in FIG. 9, it is visually recognizable that the resistance value tends to increase as the year progresses even for the same heater temperature.

The resistance value required to achieve the same heater temperature increases due to aging. Further, eventually, the heater filament may break and require repair due to temporal changes. A temporal change in the correlation is not visualized when, as in the conventional case, only a correlation graph between heater temperature and resistance value is displayed. Therefore, even when data with high resistance values relative to heater temperature exists, it may not be determined whether this is due to aging. In the meantime, as illustrated in FIG. 9, for example, by classifying sensor data by year and displaying the correlation between heater temperature and resistance value in different modes for each year, a temporal change in the resistance value required to achieve the same heater temperature is visualized, and it is possible to determine whether an increase in resistance value is due to temporal changes. When the increase in resistance value is due to temporal changes, maintenance such as replacement of the heater filament may be performed.

FIG. 10 is a diagram illustrating an example of an analysis screen that shows a correlation graph between pressure and valve angle. In FIG. 10, the correlation between the pressure inside the processing container 10 and the angle of the pressure control valve for controlling the pressure is plotted using different combinations of colors and shapes for each month. Specifically, the data for January 2023 is indicated by white squares, the data for February 2023 is indicated by triangles filled with hatching, and the data for March 2023 is indicated by black circles. As illustrated in FIG. 10, it is visually recognizable that the valve angle tends to increase as the month progresses even at the same pressure.

In a reduced-pressure CVD apparatus, when a film is formed on a substrate, reaction products are also adhered to the inside of an exhaust pipe, and therefore, the conductance of the exhaust pipe decreases as the number of processing cycles increases. Therefore, the opening degree of the pressure control valve required to achieve the same pressure inside the processing container 10 increases as the number of processing cycles increases. As illustrated in FIG. 10, for example, by classifying sensor data by month and displaying the correlation between pressure and valve angle in different modes for each month, a temporal change in the valve angle required to achieve the same pressure is visualized, and it is possible to determine whether an increase in valve angle is due to temporal changes. when the increase in valve angle is due to temporal changes, maintenance such as cleaning of the exhaust pipe may be performed.

### Effects of Embodiment

The analysis apparatus 140 according to the present embodiment acquires sensor data including a plurality of sensor values measured by the substrate processing apparatus 120 and attribute information that affects a temporal change in the substrate processing apparatus 120, classifies the sensor data based on the attribute information, and display plots corresponding to the sensor data on a correlation graph between the plurality of sensor values in different modes for each classification.

In one aspect, according to the present embodiment, since a correlation graph in which plots are displayed in a mode corresponding to an attribute that affects a temporal change in the substrate processing apparatus is displayed, it is possible to visualize a temporal change in the substrate processing apparatus. In another aspect, according to the present embodiment, since a temporal change in the correlation between sensor values may be visually recognized using only the correlation graph, it is possible to easily analyze a temporal change in the substrate processing apparatus.

The attribute information may include the execution time of a process. The attribute information may include the number of executions of a process. The attribute information may include a cumulative film thickness at the execution time of a process. In one aspect, according to the present embodiment, it is possible to analyze a temporal change in the substrate processing apparatus from various viewpoints.

The analysis apparatus 140 may display plots in different shapes for each classification. The analysis apparatus 140 may display plots in different colors for each classification. In one aspect, according to the present embodiment, the user may easily visually recognize a temporal change in the substrate processing apparatus.

The plurality of sensor values may include the temperature and resistance value of a heater provided in the substrate processing apparatus 120. In one aspect, according to the present embodiment, it is possible to easily analyze aging of the heater since a temporal change in the resistance value required to control the same temperature may be visualized.

The plurality of sensor values may include a pressure of the processing container 10 included in the substrate processing apparatus 120 and the opening degree of a valve that controls the pressure. In one aspect, according to the present embodiment, it is possible to easily analyze an increase in deposits inside the exhaust pipe since a temporal change in the opening degree of the pressure control valve required to obtain the same pressure may be visualized.

### OTHER EMBODIMENTS

A substrate processing apparatus that executes a process including a substrate processing method of the present disclosure is not limited to a thermal processing apparatus. The substrate processing apparatus may be applied to any type of apparatuses such as atomic layer deposition (ALD), capacitively coupled plasma (CCP), inductively coupled plasma (ICP), radial line slot antenna (RLSA), electron cyclotron resonance plasma (ECR), and helicon wave plasma (HWP) apparatuses.

Further, the substrate processing apparatus of the present disclosure may be applied to any apparatus that performs a predetermined processing (e.g., film formation or etching) on a substrate, regardless of whether plasma is used or not. Further, the substrate processing apparatus of the present disclosure may be applied to any of a single-sheet apparatus that processes substrates one by one, a batch apparatus that simultaneously processes a plurality of substrates, and a semi-batch apparatus that simultaneously processes a smaller number of substrates than the batch apparatus.

An information processing apparatus and a substrate processing apparatus according to the embodiment disclosed herein are merely illustrative in all respects and are not to be construed as limiting.

In one aspect, it is possible to visualize a temporal change in a substrate processing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. An information processing apparatus comprising:
acquisition circuitry configured to acquire sensor data including a plurality of sensor values measured by a substrate processing apparatus and attribute information that affects a temporal change in the substrate processing apparatus;
classification circuitry configured to classify the sensor data based on the attribute information; and
display circuitry configured to display a plot corresponding to the sensor data in a different mode for each classification, on a correlation graph between the plurality of sensor values.

2. The information processing apparatus according to claim 1, wherein the attribute information includes an execution time of a process.

3. The information processing apparatus according to claim 1, wherein the attribute information includes a number of executions of a process.

4. The information processing apparatus according to claim 1, wherein the attribute information includes a cumulative film thickness at an execution time of a process.

5. The information processing apparatus according to claim 1, wherein the display circuitry are configured to display the plot in a different shape for each classification.

6. The information processing apparatus according to claim 1, wherein the display circuitry are configured to display the plot in a different color for each classification.

7. The information processing apparatus according to claim 1, wherein the plurality of sensor values include a temperature of a heater included in the substrate processing apparatus and a resistance value of the heater.

8. The information processing apparatus according to claim 1, wherein the plurality of sensor values include a pressure of a processing container included in the substrate processing apparatus and an opening degree of a valve that controls the pressure.

9. An information processing method comprising:
acquiring, by a computer, sensor data including a plurality of sensor values measured by a substrate processing apparatus and attribute information that affects a temporal change in the substrate processing apparatus;
classifying, by a computer, the sensor data based on the attribute information; and
displaying, by a computer, a plot corresponding to the sensor data in a different mode for each classification, on a correlation graph between the plurality of sensor values.

10. A non-transitory computer-readable storage medium having stored therein a program that causes a computer to execute a process including:
acquiring sensor data including a plurality of sensor values measured by a substrate processing apparatus and attribute information that affects a temporal change in the substrate processing apparatus;
classifying the sensor data based on the attribute information; and
displaying a plot corresponding to the sensor data in a different mode for each classification, on a correlation graph between the plurality of sensor values.
